(19) United States
(12) Patent Application Publication
(10) Pub. No.: US 2011/0285391 A1
(43) Pub. Date: Nov. 24, 2011

(54) Ball Having Magnetic Field Sensor and Measuring Method

(76) Inventor: Walter Englert, Burgrieden (DE)

(21) Appl. No.: 13/124,360

(22) PCT Filed: Oct. 16, 2009
(86) PCT No.: PCT/EP2009/007449

§ 371 Date: Aug. 9, 2011

(30) Foreign Application Priority Data
Oct. 17, 2008 (DE) 10 2008 052 215.5

(51) Int. Cl. G01R 33/02

(52) U.S. Cl. 324/244

(57) ABSTRACT

A ball (100) having a magnetic field sensor (110) substantially in the centre of gravity (130) for measuring a magnetic field, the sensor being held in the centre of gravity by means of foam, springs or by a balloon, a ball with two magnetic field sensors in opposing locations on the inner wall of the ball, as well as a method of measuring magnetic field values at said locations.

### CROSS-REFERENCE TO RELATED APPLICATIONS

This application is a National Phase entry of International Patent Application No. PCT/EP2009/007449 filed 16 Oct. 2009, which claims priority to German Patent Application No. 10 2008 052 215.5 filed 17 Oct. 2008, each of which are incorporated herein.

### BACKGROUND OF THE INVENTION

The present invention relates to balls having at least one magnetic field sensor provided therein for determining a magnetic field in the ball centre of gravity, and to a method of manufacturing said balls.

For measuring the position of a ball, it was suggested in the prior art to provide in said ball a magnetic field sensor measuring an artificially created magnetic field, with the known correlation between magnetic field propagation and magnetic field strength permitting determination of the position of the ball.

As the ball during movement thereof typically can move about its own axis, it is advantageous to fix the sensor in the centre of gravity of the ball. To this end, it has already been suggested in the prior art to suspend a magnetic field sensor in the ball's centre by means of a plurality of threads.

This is problematic insofar as such rigid tensioning results in very high acceleration forces being exerted on the sensor when the ball is kicked hard, e.g. during a soccer game.

It is therefore the object of the present invention to develop an improved device for measuring a magnetic field in the centre of gravity of a ball.

This object is achieved by the subject matters of the independent claims.

Preferred embodiments are subject matter of the dependent claims.

The elastic fixation of at least one magnetic field sensor, according to the invention, is based on the finding that, on the one hand, the magnetic field sensor preferably is to be provided in the ball's centre of gravity while, on the other hand, the magnetic field sensor may suffer damage by excessively high acceleration forces.

An advantageous aspect of a preferred embodiment of the present invention thus is based on that a magnetic field sensor is fixed substantially in the centre of gravity of a ball by soft elastic foam, thereby attenuating rapid accelerations on the one hand while avoiding large deflection of the magnetic field sensor on the other hand.

A further advantageous aspect of a preferred embodiment of the present invention is based on that a magnetic field sensor is elastically fixed substantially in the centre of gravity of the ball by a plurality of springs, thereby attenuating rapid accelerations on the one hand while avoiding large deflection of the magnetic field sensor on the other hand. Still another advantageous aspect of this preferred embodiment, as compared to the prior art, is to be seen in that the springs adjust optimally to ball deformations, thus avoiding that the magnetic field sensor impinges on the inner wall of the ball and is damaged thereby.

Still another advantageous aspect of a preferred embodiment of the present invention is based on that a magnetic field sensor is provided in the middle of the flat sides of two hemispherical balloons and thus is elastically fixed substantially in the ball's centre of gravity, thereby attenuating rapid accelerations on the one hand while avoiding large deflection of the magnetic field sensor on the other hand. An additional advantageous aspect of this preferred embodiment, as compared to the prior art, is to be seen in that balloons in balls have been successfully employed for years and, thus, existing methods of manufacturing balls need to be modified only slightly.

A further advantageous aspect of a preferred embodiment of the present invention is based on that a magnetic field sensor is provided on a plurality of spherical-wedge-shaped balloons such that the magnetic field sensor is fixed elastically in the centre of gravity of a spherical balloon, so that rapid accelerations are attenuated on the one hand while large deflection of the magnetic field sensor is avoided on the other hand.

A still further advantageous aspect of a preferred embodiment of the present invention resides in that two magnetic field sensors are provided opposite one another on the inside of a ball, so that fixation in the ball's centre of gravity is rendered superfluous. The magnetic field value in the ball's centre of gravity will then be calculated preferably by interpolation.

In the following, preferred embodiments will be explained in more detail with reference to the attached drawings, wherein

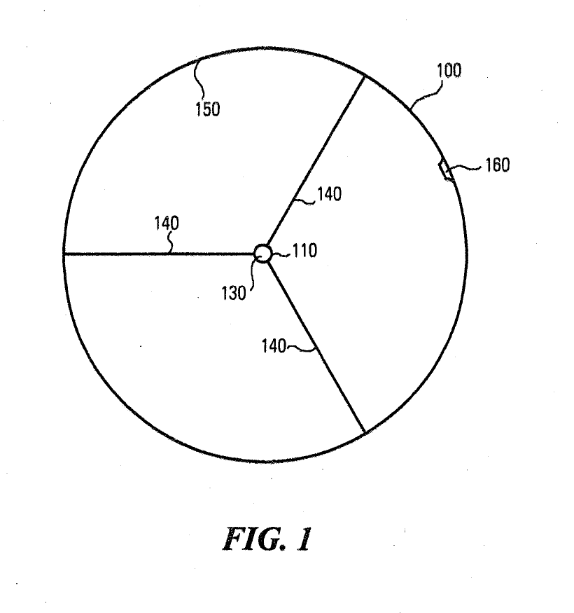

FIG. 1 shows a schematic cross-sectional view of a foam-filled ball having a magnetic field sensor provided in the centre of gravity of the ball;

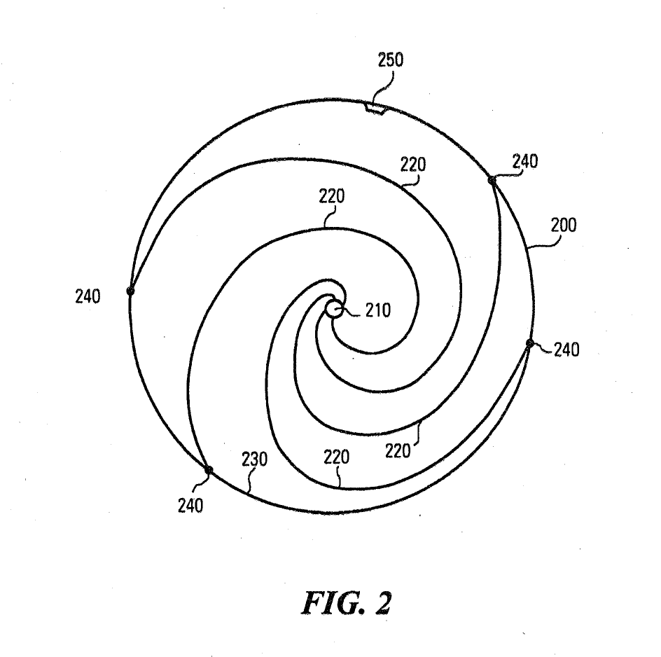

FIG. 2 shows a schematic cross-sectional view of a ball having a magnetic field sensor provided in its centre of gravity, which is fixed by a plurality of springs;

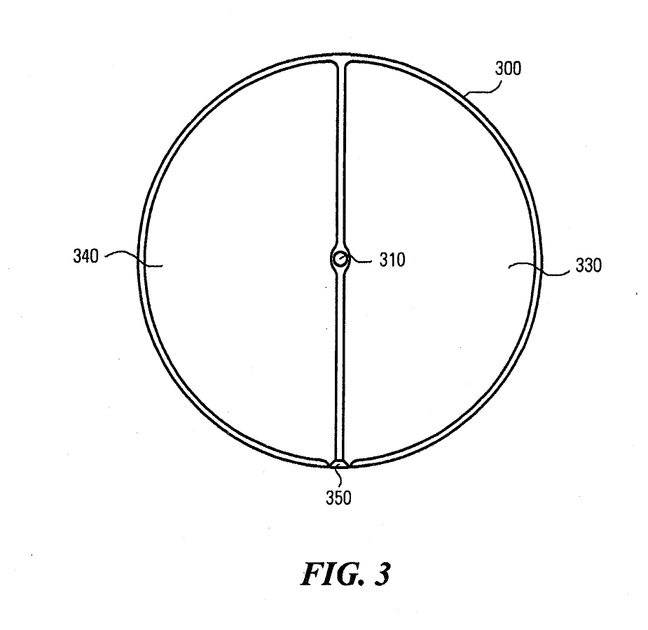

FIG. 3 shows a schematic cross-sectional view of a ball with two hemispherical balloons having a magnetic field sensor positioned in the middle of the same;

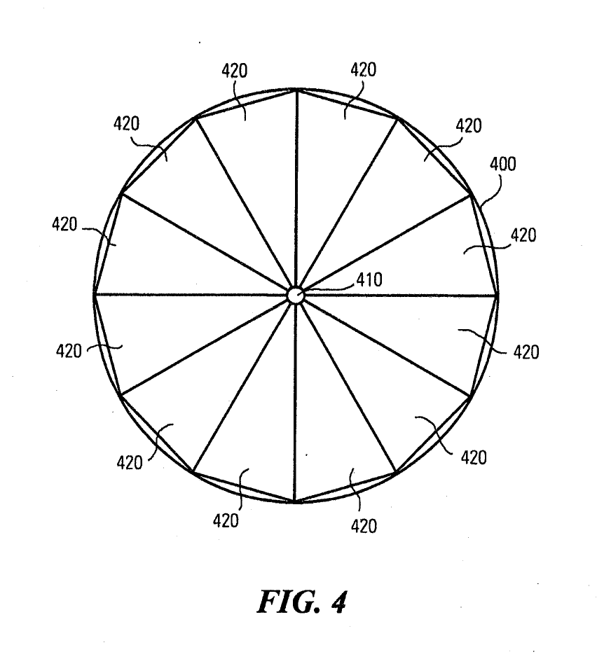

FIG. 4 shows a schematic cross-sectional view of a ball with a plurality of spherical-wedge-shaped balloons having a magnetic field sensor provided in the middle of the same; and

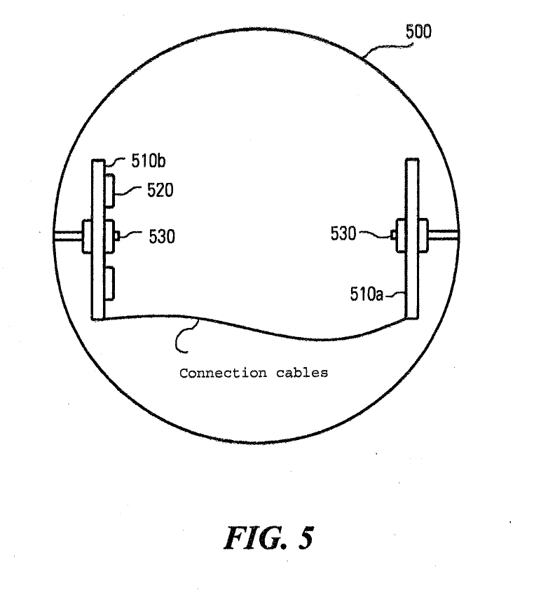

FIG. 5 shows a schematic cross-sectional view of a ball having two magnetic field sensors provided therein, which are attached to opposite sides of the inner wall of the ball.

FIG. 1 illustrates a preferred embodiment of the present invention in a schematic cross-sectional. view. In said embodiment, a magnetic field sensor (110) is provided in a foam-filled ball (100), with the magnetic field sensor (110) being fixed by the foam (120) in the centre of gravity (130) of the ball.

Prior to foam-filling of the ball (100), the magnetic field sensor (110), preferably by means of a plurality of thin plastics threads (140) which are preferably symmetrically attached to the inner wall (150) of the ball and are of equal lengths, is tensioned such that it is fixed substantially in the centre of gravity (130) of the ball (100). The ball (100) is then filled completely with foam (120).

In accordance with a preferred embodiment of the present invention, the foam (120) is a soft foam. In a particularly preferred embodiment of the present invention, the foam is soft polyurethane foam.

In order to affect the elasticity of the ball (100) as little as possible, it is important for the foam (120) to be of low density. The foam (120) preferably has a density of less than 10 kg/m³. For being able to change the internal pressure of the ball (100), preferably open-pore foam is utilized and a valve (160) is provided in the ball wall. In a preferred embodiment of the present invention, polyether foam is used.

The tensile strength of the attaching threads (140) preferably is selected such that they do not withstand rapid accelerations of the ball (100) so that, upon complete reaction of the foam (120), the magnetic field sensor is fixed in the centre of gravity of the ball (100) solely by the completely reacted foam (120).

For transferring the sensor values measured, the sensor (110) is connected to a transmission unit, preferably a radio transmitter. The radio transmitter operates preferably in the 2.4 GHz range.

For supplying power to the magnetic field sensor (110), an accumulator or battery is provided according to a preferred embodiment of the present invention. Said battery is preferably rechargeable via induction coils.

In accordance with an alternative embodiment, no battery is provided and the magnetic field sensor (110) and the radio transmitter make use of induction energy.

FIG. 2 illustrates a preferred development of the present invention in a schematic cross-sectional view. FIG. 2 shows a ball (200) having a magnetic field sensor (210) provided therein, with the magnetic field sensor (210) being fixed substantially in the centre of gravity of the ball (200) by a plurality of springs (220) in contact with the ball interior (230). In accordance with a preferred embodiment of the present invention, the springs (200) are flexural springs. In accordance with a particularly preferred embodiment of the present invention, the springs (200) are leaf springs.

For preventing damage to the inside of the ball (200) by sharp edges, a plastics cap (240) is provided on each spring end according to a preferred embodiment of the present invention.

During manufacture of the ball (200), the springs (220) preferably are wrapped around the magnetic field sensor (210), fixing the latter in this state. After inflation of the ball (200) via valve (250), the fixations are released, with the elasticity of the springs (200) having the effect that the magnetic field sensor (210) is fixed substantially in the centre of gravity of the ball (200). To this end, preferably springs (200) of equal lengths are selected.

In accordance with a preferred embodiment of the present invention, fixation is obtained by means of a temperature-sensitive polymer, which permits release of the fixation by heating. In accordance with a specially preferred embodiment, the polymer is a low-temperature thermoplastic material having a melting temperature below 50° C.

For transmitting the measured values of the magnetic field sensor (210), the latter is connected to a transmission unit, preferably a radio transmitter. The radio transmitter operates preferably in the 2.4 GHz range.

For supplying power to the magnetic field sensor (210), a battery is provided according to a preferred embodiment of the present invention. Said battery is preferably rechargeable via induction coils.

In accordance with an alternative embodiment, no battery is provided and the magnetic field sensor (210) and the radio transmitter make use of induction energy.

FIG. 3 illustrates a preferred development of the present invention in a schematic cross-sectional view. The view shows two hemispherical balloons (330) (340) within the ball (300). In addition, a magnetic field sensor (310) is provided in the middle of the flat sides of the hemispherical balloons (330) (340). The balloons (330) (340) preferably consist of natural rubber.

During manufacture of the ball (300), the magnetic field sensor (310) is connected to both of the hemispherical balloons (330) (340) and introduced into the ball (300). Both balloons (330) (340) are connected to a valve (350) permitting inflation of the two balloons (330) (340) to the same pressure. By fixation of the magnetic field sensor (310) in the middle of the flat side of both balloons (330) (340), it is ensured that the magnetic field sensor (310) is fixed substantially in the centre of gravity of the ball (300).

In an alternative embodiment of the present invention, both of the hemispherical half-balloons have perforations on their flat sides, with the two hemispherical half-balloons being adhered to each other such that the two hemispherical balloons are connected to each other by the mutual perforations.

For transmitting the measured values of the magnetic field sensor (310), the latter is connected to a transmission unit, preferably a radio transmitter. The radio transmitter operates preferably in the 2.4 GHz range.

For supplying power to the magnetic field sensor (310), a battery is provided according to a preferred embodiment of the present invention. Said battery is preferably rechargeable via induction coils.

In accordance with an alternative embodiment, no battery is provided and the magnetic field sensor (310) and the radio transmitter make use of induction energy.

FIG. 4 illustrates a preferred development of the present invention in a schematic cross-sectional view. A plurality of spherical-wedge-shaped balloons (420) is provided within a ball (400). According to a preferred embodiment of the present invention, the balloons (420) consist of natural rubber. In addition, the balloons (420) are inflated preferably via a valve.

In accordance with a preferred embodiment, the spherical-wedge-shaped balloons (420) are flattened on their pointed side, thereby creating a duct transversely through the spherical shape formed by the plurality of the spherical-wedge-shaped balloons (420). The magnetic field sensor (410) is introduced in said duct preferably prior to inflation of the balloons (420). After inflation of the balloons (420), the magnetic field sensor (410) is fixed substantially in the centre of gravity of the ball (400).

FIG. 5 illustrates a preferred development of the present invention in a schematic cross-sectional view. The magnetic field sensors are, according to FIG. 5, mutually fixed to the inner wall of the ball (500). In this case, both magnetic field sensors are preferably potted in modular discs (510). In accordance with a particularly preferred embodiment, one modular disc (510a) is provided on the valve, and the other modular disc (510b) is provided as a counterweight on the opposite side.

The modular disc (510a) on the valve carries, in addition to the magnetic field sensor, a radio transmitter with antenna as well as a CPU. On the opposite modular disc (510b), there is provided the battery (520) which is attached such that it is located on the side facing the interior of the ball.

In accordance with an alternative embodiment, no battery is provided and the magnetic field sensor and the radio transmitter make use of induction energy.

The measured values of both sensors are utilized to determine the expected measurement value in the centre of the ball (500). With respect to the magnetic field strength, this is achieved preferably by simple averaging.

In accordance with a specially preferred embodiment of the present invention, both modular discs (510) are connected to flexible circuit boards.

1. A ball (100) filled completely with foam (120) in its interior and having a magnetic field sensor (110) substantially in the centre of gravity (130) for measuring a magnetic field, wherein said foam (120) fixes the position of the magnetic field sensor (110).

2. A ball (100) according to claim 1, further characterized in that said foam (120) is soft foam.

3. A ball (100) according to claim 2, further characterized in that said foam (120) is PUR soft foam.

4. A ball (100) according to claim 3, further characterized in that said foam (120) contains latex.

5. A ball (100) according to claim 4, further characterized in that said foam (120) is an open-pore foam.

6. A ball (100) according to claim 5, further characterized in that said foam (120) is polyether foam.

7. A ball (100) according to claim 6, further characterized in that said foam (120) has a density below 10 kg/m³.

8. A ball (200) having a magnetic field sensor (210) in its interior, wherein said magnetic field sensor (210) has a plurality of springs (220) of equal lengths provided thereon that abut on the inner wall (230) of the ball and thereby fix the magnetic field sensor (210) substantially in the centre of gravity of the ball (200).

9. A ball (200) according to claim 8, further characterized in that each spring end has a plastics cap (240) provided thereon.

10. A ball (200) according to claim 8, further characterized in that said springs (220) are flexural springs.

11. A ball (200) according to claim 10, further characterized in that said springs (220) are leaf springs.

12. A ball (300) having two hemispherical balloons (330) (340) which are provided, in the middle of their flat side, with a magnetic field sensor (310) for measuring a magnetic field substantially in the centre of gravity of the ball (300).

13. A ball (300) according to claim 12, further characterized in that said balloons (330) (340) consist of natural rubber.

14. A ball (300) according to claim 13, further characterized in that that both balloons (330) (340) are inflated via a valve (350).

15. A ball comprising a plurality of spherical-wedge-shaped balloons, wherein the spherical-wedge-shaped balloons in their entirety constitute a sphere and the spherical-wedge-shaped balloons are rounded towards the middle of the sphere and, in the middle of the resultant duct, there is provided a magnetic field sensor for measuring a magnetic field.

16. A ball according to claim 15, further characterized in that said balloons consist of natural rubber.

17. A ball according to claim 16, further characterized in that said balloons are inflated via a valve.

18. A ball comprising two magnetic field sensors for measuring magnetic fields, wherein said magnetic field sensors are provided in opposing locations on the inner wall of the ball.

19. A ball according to claim 18, further characterized in that the magnetic field sensors are potted in modular discs.

20. A ball according to claim 19, further characterized in that the modular discs are connected to flexible circuit boards.

21. A ball according to claim 20, further characterized in that one modular disc is attached to the valve.

22. A ball according to claim 21, further characterized in that a radio transmitter with antenna and a CPU are provided in the modular disc at said valve.

23. A ball according to claim 22, further characterized in that said modular disc opposite said valve carries a battery, the battery being provided on the side of the modular disc facing away from the ball interior.

24. A method of measuring magnetic field values in the centre of gravity of a ball (100), said method comprising the steps of:
suspending a magnetic field sensor (110) in the centre of gravity of the ball (100); and
filling the ball (100) with foam such that said magnetic field sensor (110) is fixed by the foam (120) in the centre of the ball (100); and
measuring the magnetic field in the ball's centre of gravity (130).

25. A method according to claim 24, further characterized in that said foam (120) is soft foam.

26. A method according to claim 25, further characterized in that said foam (120) is PUR soft foam.

27. A method according to claim 26, further characterized in that said foam (120) contains latex.

28. A method according to claim 27, further characterized in that said foam (120) is an open-pore foam.

29. A method according to claim 28, further characterized in that said foam (120) is polyether foam.

30. A method according to claim 29, further characterized in that said foam (120) has a density below 10 kg/ms.

31. A method of measuring magnetic field values in the centre of gravity of a ball (200), said method comprising the steps of:
wrapping a plurality of elastic springs (220) of equal lengths around a magnetic field sensor (210);
fixing the spring ends to the magnetic field sensor (210);
introducing the wrapped magnetic field sensor (210) into the ball (200); and
releasing the fixation of the spring ends on the magnetic field sensor (210), so that the elastic springs (220) align and the magnetic field sensor (210) is fixed substantially in the centre of gravity of the ball (200); and
measuring the magnetic field in the ball's centre of gravity.

32. A method according to claim 31, further characterized in that a plastics cap (240) is provided at the ends of each spring (220).

33. A method according to claim 32, further characterized in that said springs (220) are flexural springs.

34. A method according to claim 33, further characterized in that said springs (220) are leaf springs.

35. A method according to claim 31, further characterized in that said fixation is released by heating.

36. A method according to claim 35, further characterized in that said fixation is achieved by means of a polymer.

37. A method according to claim 36, further characterized in that said polymer is a low-temperature thermoplastic material.

38. A method according to claim 37, further characterized in that said low-temperature thermoplastic material has a melting temperature of less than 50° C.

39. A method of measuring magnetic field values in the centre of gravity of a ball (300), said method comprising the steps of:
attaching a magnetic field sensor (310) in the middle of the flat sides of two hemispherical balloons (330) (340);
introducing the hemispherical balloons (330) (340) and the magnetic field sensor (310) into a ball (300); and
inflating the balloons (330) (340); and
measuring the magnetic field in the ball's centre of gravity.

40. A method according to claim 39, further characterized in that said balloons (330) (340) consist of natural rubber.

41. A method according to claim 39, further characterized in that said both balloons (330) (340) are inflated via the same valve (350).

42. A method of measuring magnetic field values in the centre of gravity of a ball, said method comprising the steps of:
introducing a plurality of spherical-wedge-shaped balloons into the ball, with the entirety of the spherical-wedge-shaped balloons constituting a sphere and the spherical-wedge-shaped balloons being rounded towards the middle of the sphere such that a duct through the resultant sphere is formed;
inflating the balloons; and
introducing a magnetic field sensor along said duct into the centre of the sphere constituted by the balloons; and
measuring the magnetic field in the ball centre,

43. A method method according to claim 42, further characterized in that said balloons consist of natural rubber.

44. A method according to claim 42, further characterized in that said balloons are inflated via a valve.

45. A method of measuring magnetic field values in the centre of a ball, said method comprising the steps of:
mounting two magnetic field sensors in opposing locations on the inner wall of the ball;
measuring the magnetic fields at the locations of both sensors; and
determining the magnetic field in the centre of the ball by averaging the two magnetic field values measured.

46. A method according to claim 45, further characterized in that the magnetic field sensors are potted in modular discs.

47. A method according to claim 46, further characterized in that the modular discs are connected to flexible circuit boards.

48. A method according to claim 47, further characterized in that one modular disc is attached to the valve.

49. A method according to claim 48, further characterized in that a radio transmitter with antenna and a CPU are provided in the modular disc at said valve.

50. A method according to claim 49, further characterized in that said modular disc opposite said valve carries a battery, the battery being provided on the side of the modular disc facing away from the ball interior.
